(19) United States
(12) Patent Application Publication
(10) Pub. No.: US 2011/0248282 A1
(43) Pub. Date: Oct. 13, 2011

(54) SEMICONDUCTOR STRUCTURE AND MANUFACTURING METHOD OF THE SAME

(75) Inventors: Haizhou Yin, Poughkeepsie, NY (US); Huilong Zhu, Poughkeepsie, NY (US); Zhijiong Luo, Poughkeepsie, NY (US)

(73) Assignee: Institute of Microelectronics, Chinese Academy of Sciences, Beijing (CN)

(21) Appl. No.: 12/912,498

(22) Filed: Oct. 26, 2010

(30) Foreign Application Priority Data
Apr. 9, 2010 (CN) 201010145265.2

(51) Int. Cl. H01L 29/20; H01L 21/20

(52) U.S. Cl. 257/76; 438/478; 257/E29.089

(57) ABSTRACT

The invention provides a semiconductor structure and a manufacturing method of the same, and relates to a field of semiconductor manufacture. The semiconductor structure comprises: a silicon substrate; a large bandgap semiconductor layer formed on the silicon substrates; and a silicon layer formed on the large bandgap semiconductor layer. The method comprises: growing a large bandgap semiconductor layer on a silicon substrate; and growing a silicon layer on the large bandgap semiconductor layer. The embodiments of the present invention can be applied to manufacture of semiconductor devices.

### BACKGROUND OF THE INVENTION

1. Field of the Invention

The invention relates to the technology of semiconductor manufacture, and more particularly to a semiconductor structure and a manufacturing method of the same.

2. Description of the Prior Art

A prevalent trend in modern integrated circuit manufacture is to produce semiconductor devices, such as memory cells, with reducing sizes.

Manufacturing nanometer-size transistors enables integrating more transistors in a single chip, so that a larger circuit system can be built in a smaller area. However, the continuously reducing size of the transistor causes the channel length to reduce, and therefore induces severe short channel effects (SCE).

Ultra Thin Silicon on Insulator (UTSOI) is a typical technology for suppressing the SCE. As shown in FIG. 1, in an SOI structure 100, a silicon dioxide layer 102 is arranged between a silicon substrate 101 and a top silicon layer 103 as an insulating layer, and is referred to as a buried oxide layer (BOX). An ultra thin silicon channel provided by the device of UTSOI limits the depths of the source region and the drain region, improves the capability of the gate in controlling the channel, and therefore suppresses the SCE.

Currently, the UTSOI is typically manufactured by wafer bonding. Manufacturing the UTSOI by wafer bonding is demanding in process and easy to cause lattice defects on the interface, and consequently difficult to get good yields. Further, as the thickness of the ultra thin silicon layer is difficult to control, the uniformity of the top silicon layer 103 on the BOX is unsatisfactory.

### SUMMARY OF THE INVENTION

It is thus desired to provide a semiconductor structure, which has a similar capability of suppressing the SCE as the UTSOI and a more stable performance, and is easier to be manufactured, and a manufacturing method of the same.

According to an aspect of the present invention, a semiconductor structure comprises: a silicon substrate; a large bandgap semiconductor layer formed on the silicon substrate layer; and a silicon layer formed on the large bandgap semiconductor layer.

According to another aspect of the present invention, a method for manufacturing a semiconductor structure comprises: growing a large bandgap semiconductor layer on a silicon substrate; and growing a silicon layer on the large bandgap semiconductor layer.

Based on the above solutions, preferably, the large bandgap semiconductor layer can be formed of any one of GaP, GaAs, and AlAs, or any combination thereof.

Preferably, the large bandgap semiconductor layer comprises at least one layer, and the thickness of the large bandgap semiconductor layer is 5˜50 nm.

Preferably, the thickness of the silicon layer is 5˜20 nm.

The large bandgap semiconductor layer is formed of a large bandgap semiconductor material with a bandgap larger than 1.5 eV. The difference between the lattice constant of the large bandgap semiconductor material and that of Si is less than or equal to 2%.

The technical solutions of the embodiments of the present invention solve the problem that the manufacture of UTSOI is demanding in process and difficult to get good yields. The semiconductor device manufactured according to the embodiments of the present invention can effectively suppress the SCE of the device and improve the electrical and physical performances.

### BRIEF DESCRIPTION OF THE DRAWINGS

The embodiments will be described in an exemplary but unlimited manner with reference to the accompany drawings, in which corresponding or similar elements are represented by similar reference signs, wherein:

FIG. 1 is a schematic view of the structure of the SOI of the prior art;

FIG. 2 is a schematic view of the semiconductor structure according to an embodiment of the present invention;

FIG. 3 shows a relationship between the energy gap and the lattice constant of commonly used semiconductor materials; and

FIG. 4 is a flow chart of the manufacturing method of the semiconductor structure according to an embodiment of the present invention.

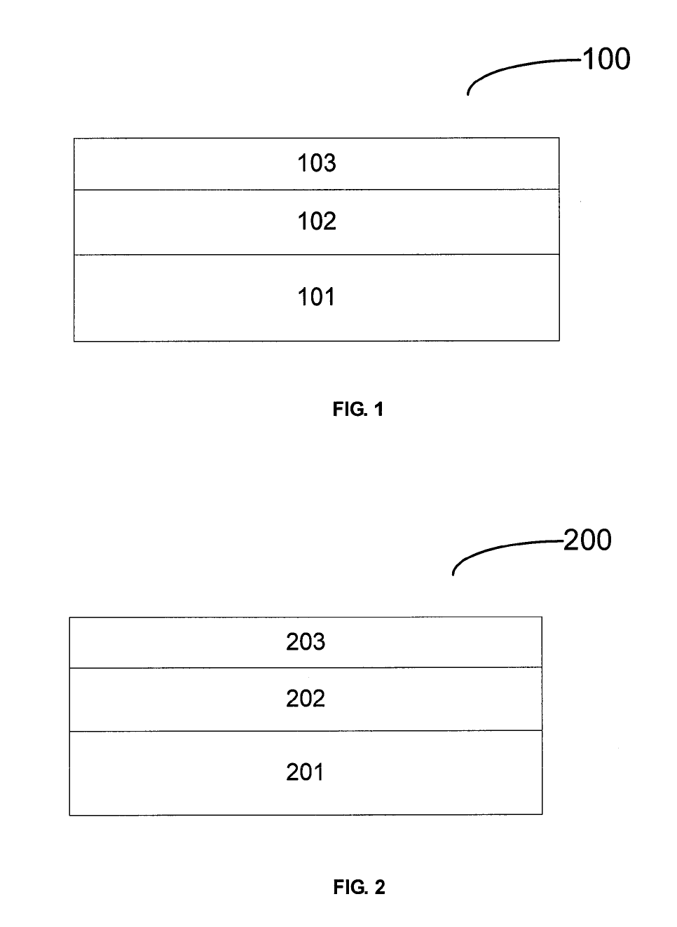

### DETAILED DESCRIPTION OF THE PREFERRED EMBODIMENTS

The embodiments of the present invention provide a semiconductor structure and a manufacturing method of the same, which solve the problem that the process of UTSOI is demanding and difficult to get good yields and can effectively suppress the SCE.

FIG. 2 is a schematic view of the structure of a semiconductor structure 200 according to an embodiment of the present invention. As shown in FIG. 2, the semiconductor 200 includes a silicon substrate 201, one or more large bandgap semiconductor layers 202 formed on the silicon substrate, and a silicon layer 203 formed on the one or more large bandgap semiconductor layers 202. The thickness of the one or more large bandgap semiconductor layers 202 is preferably 5˜50 nm, and the thickness of the silicon layer 203 is preferably 5˜20 nm. The top silicon layer 203 is also referred to as a top silicon.

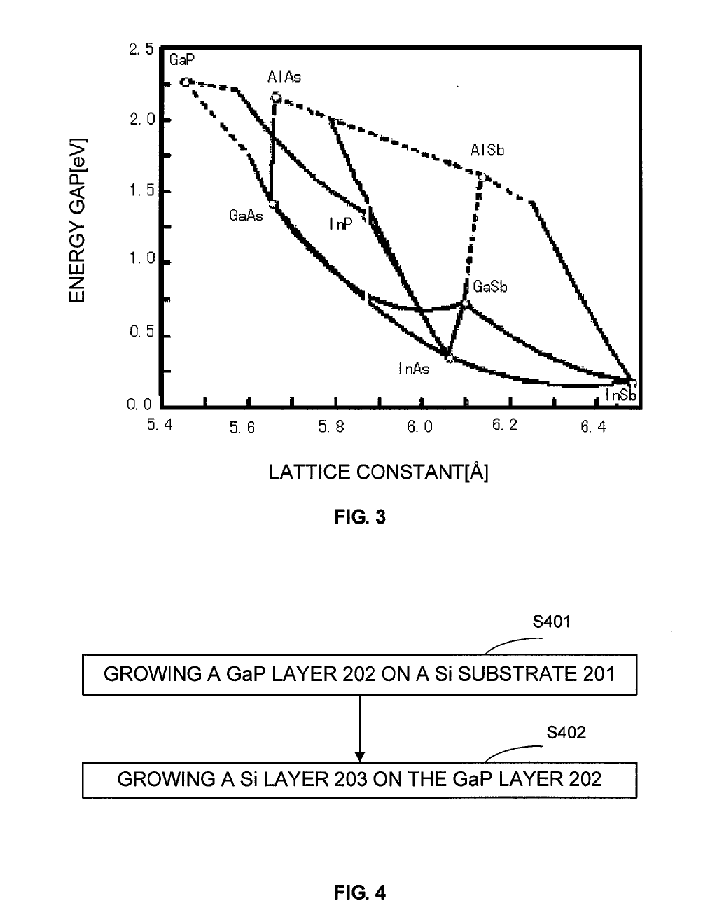

FIG. 3 shows the relationship between the energy gap and the lattice constant of the commonly-used semiconductor materials. The lattice constant of silicon is 5.43 Å, and the bandgap of silicon is 1.1 eV. Materials, such as GaP, GaAs, AlAs, and any combination thereof, which have lattice constants close to that of silicon and an energy gap larger than that of silicon, can be selected to form the large bandgap semiconductor layer 202. In an embodiment of the present invention, the intermediate large bandgap semiconductor layer is formed of GaP. GaP has a lattice constant that is very close to that of Si and has a very large energy gap. Typically, a semiconductor material having an energy gap larger than 1.5 eV is deemed as a large bandgap semiconductor material. Preferably, the difference between the lattice constant of the large bandgap semiconductor material and that of the Si is not larger than 2%. For example, the lattice constant of silicon is 5.43 Å, and the lattice constant of the selected large bandgap semiconductor material is preferably between 5.3 Å˜5.5 Å, in order to effectively avoid lattice defects induced in epitaxial growth. The lattice constant of the semiconductor material to be selected also depends on the thicknesses of the large bandgap semiconductor layer and the top silicon to be formed. In general, if the difference between the lattice constant of the large bandgap semiconductor material and that of the Si is large, the large bandgap semiconductor layer and the top silicon should not be too thick, in order to avoid lattice defects.

The embodiment of the present invention replaces the oxide layer in the SOI with the large bandgap semiconductor material in the substrate for manufacturing the semiconductor device, such that the ultra thin silicon channel formed in the device limits the depths of the source region and the drain region. As a consequence, the capability of the gate in controlling the channel is improved and the SCE of the semiconductor device is suppressed. Furthermore, since the lattice constant of the large bandgap semiconductor material used in the embodiment of the present invention is very close to that of silicon, a good lattice structure on the interface can be ensured.

Although the drawing only shows one large bandgap semiconductor layer 202, one or more large bandgap semiconductor layers 202 can be provided, each of which is formed of the above-mentioned large bandgap semiconductor material or any combination thereof. The large bandgap semiconductor material has a crystalline structure, so it is commensurately strained and can match the lattice structure of the semiconductor substrate material. In the semiconductor structure formed according to the embodiment of the present invention, the large bandgap semiconductor layer has a crystalline structure and can better facilitate the epitaxial growth of the source/drain region of the semiconductor than the amorphous oxide layer in the UTSOI.

The embodiment of the present invention is not limited thereto. For example, multiple large bandgap semiconductor layers can be formed, each of which is formed of a different material. The material forming each layer can be GaP, GaAs, AlAs, etc., or any combination thereof.

The semiconductor device can have a small leakage current by using the semiconductor material with a large energy gap as a part of the substrate of the semiconductor device.

FIG. 4 shows a flow chart for manufacturing the semiconductor structure according to an embodiment of the present invention. In step S401, a GaP layer 202 is grown on a silicon substrate 201 by epitaxial growth.

Those skilled in the art will understand that besides the GaP layer, other large bandgap semiconductor layers can also be grown, such as large bandgap semiconductor layers formed of GaAs, AlAs, etc., or any combination thereof. The large bandgap semiconductor layers can also be grown by other technologies, such as the deposition technique well known to those skilled in the art, etc.

One or more large bandgap semiconductor layers can be grown. In case of one large bandgap semiconductor layer, the thickness of the large bandgap semiconductor layer is preferably 5˜50 nm. In case of multiple bandgap semiconductor layers, the total thickness of the multiple bandgap semiconductor layers is preferably 5˜50 nm. In case of growing multiple bandgap semiconductor layers, a different material selected from GaP, GaAs, AIAs, etc., or any combination thereof, can be grown in each layer. Alternatively, a same material can be grown in the multiple layers.

According to the method of the embodiment of the present invention, the thickness of the large bandgap semiconductor layer can easily be controlled and adjusted as required, such that the SCE of the device can be well suppressed.

Next, in step S402, a silicon layer 203 with the thickness of 5˜20 nm is grown on the GaP layer 202. Likewise, the silicon layer can be grown by epitaxial growth or deposition technique. The thickness of the top silicon in the UTSOI is typically less than 30 nm and the uniformity of the top silicon is difficult to control. The thickness of the top silicon can be better controlled by means of growing the top silicon by epitaxial growth or deposition than by wafer bonding technique, and the uniformity of the top silicon layer is better.

Growing the large bandgap semiconductor layer on the silicon substrate, growing other large bandgap semiconductor layers on one large bandgap semiconductor layer, and growing the silicon layer on the large bandgap semiconductor layer by epitaxial growth or deposition is well known to those skilled in the art. Therefore, the detailed description on epitaxial growth or deposition is omitted, in order to avoid unnecessarily obscuring the subject matter of the present invention.

The manufacturing method of the semiconductor structure according to the embodiment of the present invention avoids the massive lattice defects on the interface due to atom compression in the wafer bonding technique. The embodiment of the present invention forms the large bandgap semiconductor layer and the top silicon by means of epitaxial growth or deposition, such that the thickness of the large bandgap semiconductor layer and the top silicon can be well controlled.

The manufacturing method of the semiconductor structure according to the present invention does not need wafer bonding, but only needs the inexpensive and simple epitaxial growth or deposition, and consequently can substantially reduce the process complexity and cost. The thickness of the top silicon can be precisely controlled and has a better uniformity than the top silicon formed by polish. Meanwhile, the silicon layer grown by epitaxial growth has a more regular lattice structure and facilitates the subsequent growth of the source and drain regions. Further, compared with the BOX in the UTSOI, the large bandgap semiconductor layer grown by epitaxial growth can be very thin, and thus can further suppress the SCE.

The present invention has been described in conjunction with the embodiments thereof. However, those skilled in the art will understand that other modifications or variations are possible without departing from the scope defined by the appended claims, and all of such modifications and variations are within the protection scope of the present invention.

1. A semiconductor structure, comprising:
a silicon substrate;
a large bandgap semiconductor layer formed on the silicon substrate; and
a silicon layer formed on the large bandgap semiconductor layer.

2. The semiconductor structure according to claim 1, wherein the large bandgap semiconductor layer is formed of any one of GaP, GaAs, and AlAs, or any combination thereof.

3. The semiconductor structure according to claim 1, wherein the large bandgap semiconductor layer comprises at least one layer.

4. The semiconductor structure according to claim 1, wherein the thickness of the large bandgap semiconductor layer is 5˜50 nm.

5. The semiconductor structure according to claim 1, wherein the thickness of the silicon layer is 5˜20 nm.

6. The semiconductor structure according to claim 1, wherein the large bandgap semiconductor layer is formed of a large bandgap semiconductor material with a energy gap larger than 1.5 eV.

7. The semiconductor structure according to claim 1, wherein the difference between the lattice constant of the semiconductor material of the large bandgap semiconductor layer and that of Si is less than or equal to 2%.

8. A method for manufacturing a semiconductor, comprising:
growing a large bandgap semiconductor layer on a silicon substrate; and
growing a silicon layer on the large bandgap semiconductor layer.

9. The method according to claim 8, wherein growing the large bandgap semiconductor layer on the silicon substrate comprises:
growing the large bandgap semiconductor layer formed of any one of GaP, GaAs, and AlAs, or any combination thereof.

10. The method according to claim 8, wherein growing the large bandgap semiconductor layer on the silicon substrate comprises:
growing at least one large bandgap semiconductor layer on the silicon substrate.

11. The method according to claim 8, wherein the thickness of the large bandgap semiconductor layer is 5˜50 nm.

12. The method according to claim 8, wherein the thickness of the silicon layer is 5˜20 nm.

13. The method according to claim 8, wherein the large bandgap semiconductor layer is formed of a large bandgap semiconductor material with a energy gap larger than 1.5 eV.

14. The method according to claim 8, wherein the difference between the lattice constant of the semiconductor material of the large bandgap semiconductor layer and that of Si is less than or equal to 2%.
